(19) United States
(12) Patent Application Publication
(10) Pub. No.: US 2026/0118394 A1
(43) Pub. Date: Apr. 30, 2026

(54) ELECTRONIC DEVICE AND METHOD TO ESTIMATE INPUT POWER INTO RESONANT TANK IN RESONANT CIRCUIT

(71) Applicant: Delta Electronics, Inc., Taoyuan City (TW)

(72) Inventors: Chun-Wei LIN, Taoyuan City (TW); Ming-Shi HUANG, Taoyuan City (TW); Jhih-Cheng HU, Taoyuan City (TW); Yi-Min CHEN, Taoyuan City (TW)

(21) Appl. No.: 19/280,839

(22) Filed: Jul. 25, 2025

(30) Foreign Application Priority Data
Oct. 24, 2024 (CN) 202411491144.1

(51) Int. Cl. G01R 21/06; G01R 25/00; H02M 5/458

(52) U.S. Cl. CPC G01R 21/06; G01R 25/00; H02M 5/458

(57) ABSTRACT

An electronic device to calculate input power input to a resonant tank in a resonant circuit includes a bandpass filter, a phase detection circuit, a peak detection circuit, and a processor. The bandpass filter receives a resonant current input to the resonant tank, and filters the resonant current to generate a first baseband current. The phase detection circuit calculates a phase difference between the first baseband current and a resonant tank voltage input to the resonant tank. The peak detection circuit generates a baseband current peak value according to the first baseband current. The processor performs a fast Fourier transform on the resonant tank voltage to obtain a resonant tank baseband voltage. The processor calculates the input power according to the resonant tank baseband voltage, the baseband current peak value, and the phase difference.

### CROSS REFERENCE TO RELATED APPLICATIONS

This application claims the benefit of China Patent Application No. 202411491144.1, filed on Oct. 24, 2024, the entirety of which is incorporated by reference herein.

### BACKGROUND OF THE INVENTION

### Field of the Invention

The present invention relates to an electronic device, and, in particular, it relates to an electronic device and a method to estimate input power into a resonant tank in a resonant circuit.

### Description of the Related Art

Traditional power estimation technology uses high-speed sampling of a voltage signal and a current signal input to the resonant tank, multiplies and integrates the voltage signal and the current signal, and averages them to obtain input power. The above estimation process is complex and requires a microprocessor with high-order operations to execute.

### BRIEF SUMMARY OF THE INVENTION

An embodiment of the present invention provides an electronic device. The electronic device includes a bandpass filter, a phase detection circuit, a peak detection circuit, and a processor. The bandpass filter receives a resonant current input to the resonant tank, and filters the resonant current to generate a first baseband current. The phase detection circuit is electrically connected to the bandpass filter, and calculates a phase difference between the first baseband current and the rising edges of a resonant tank voltage input to the resonant tank. The peak detection circuit is electrically connected to the bandpass filter, and generates a baseband current peak value according to the first baseband current. The processor performs a fast Fourier transform on the resonant tank voltage to obtain a resonant tank baseband voltage. The processor is electrically connected the phase detection circuit and the peak detection circuit, and calculates the input power according to the resonant tank baseband voltage, the baseband current peak value, and the phase difference.

According to the electronic device described above, the processor calculates the input power using the following equation:

$${P}_{r} = \frac{11}{9 π} {V}_{rp 1} {I}_{r p , P D C} cos ( {θ}_{v 1} - {θ}_{i 1} ) .$$

Pᵣ is the input power, Vᵣₚ₁ is the resonant tank baseband voltage, I_{rp,PDC} is the baseband current peak value, and θᵥ₁−θᵢ₁ is the phase difference between the first baseband current and the rising edge of the resonant tank voltage.

The electronic device further includes a subtractor. The subtractor is electrically connected to the processor. The subtractor receives reference input power and the input power from the processor, and subtracts the reference input power and the input power to obtain the power difference.

The electronic device further includes a power regulator. The power regulator is electrically connected to the subtractor. The power regulator adjusts the input power according to the power difference to obtain the total input power.

The electronic device further includes a pulse frequency modulation circuit. The pulse frequency modulation circuit is electrically connected to the power regulator. The pulse frequency modulation circuit adjusts the frequency of a pulse signal according to the total input power, and outputs the pulse signal.

The electronic device further includes a gate driving circuit. The gate driving circuit is electrically connected to the pulse frequency modulation circuit. The gate driving circuit drives the resonant circuit according to the pulse signal.

According to the electronic device described above, the input power includes baseband power and maximum sideband power.

According to the electronic device described above, the resonant circuit is an inductor-inductor-capacitor (LLC) circuit, or a resonant circuit for wireless energy transmission, or a resonant circuit of an induction cooker.

An embodiment of the present invention provides a method to estimate input power input to a resonant tank in a resonant circuit. The method includes the following steps. A resonant current input to the resonant tank is received, and the resonant current is filtered to generate a first baseband current. A phase difference between the first baseband current and the rising edges of a resonant tank voltage input to the resonant tank is calculated. A baseband current peak value is generated according to the first baseband current. A fast Fourier transform is performed on the resonant tank voltage to obtain a resonant tank baseband voltage. The input power is calculated according to the resonant tank baseband voltage, the baseband current peak value, and the phase difference.

According to the method described above, the step of calculating the input power according to the resonant tank baseband voltage, the baseband current peak value, and the phase difference includes the following step. The input power is calculated using an equation. The equation is

$${P}_{r} = \frac{11}{9 π} {V}_{rp 1} {l}_{r p , P D C} cos ( {θ}_{v 1} - {θ}_{i 1} ) .$$

Pᵣ is the input power, Vᵣₚ₁ is the resonant tank baseband voltage, I_{rp,PDC} is the baseband current peak value, and θᵥ₁−θᵢ₁ is the phase difference between the first baseband current and the rising edge of the resonant tank voltage.

The method further includes the following steps. Reference input power is received, and the reference input power and the input power are subtracted to obtain the power difference. The input power is adjusted according to the power difference to obtain the total input power. The frequency of a pulse signal is adjusted according to the total input power, and the pulse signal is output. The resonant circuit is driven according to the pulse signal.

### BRIEF DESCRIPTION OF THE DRAWINGS

The present invention can be more fully understood by reading the subsequent detailed description and examples with references made to the accompanying drawings, wherein:

FIG. 1 is a schematic diagram of an electronic device 100 in accordance with some embodiments of the present invention.

FIG. 2 is a waveform diagram of an input voltage Vᵢₙ(t), a resonant tank voltage Vᵣₚ(t), and a resonant current iᵣₚ(t) in a resonant circuit 102 of FIG. 1 in accordance with some embodiments of the present invention.

FIG. 3A is a spectrum diagram of the resonant tank voltage Vᵣₚ in the resonant circuit 102 of FIG. 1 based on a switching frequency fₛ in accordance with some embodiments of the present invention.

FIG. 3B is a spectrum diagram of the resonant tank voltage Vᵣₚ in the resonant circuit 102 of FIG. 1 based on a mains frequency f_{ac} in accordance with some embodiments of the present invention.

FIG. 3C is a spectrum diagram of the resonant tank voltage Vᵣₚ in the resonant circuit 102 of FIG. 1 based on the switching frequency fₛ and the sideband frequency fₛ±kf_{ac} in accordance with some embodiments of the present invention.

FIG. 4A a spectrum diagram of the resonant current iᵣₚ in the resonant circuit 102 of FIG. 1 based on the switching frequency fₛ in accordance with some embodiments of the present invention.

FIG. 4B a spectrum diagram of the resonant current iᵣₚ in the resonant circuit 102 of FIG. 1 based on the mains frequency f_{ac} in accordance with some embodiments of the present invention.

FIG. 4C a spectrum diagram of the resonant current iᵣₚ in the resonant circuit 102 of FIG. 1 based on the switching frequency fₛ and the sideband frequency fₛ±kf_{ac} in accordance with some embodiments of the present invention.

FIG. 5 is a diagram of a relationship between a resonant tank impedance |Zₚₙ| and both the switching frequency fₛ and its harmonic frequency in the resonant circuit 102 of FIG. 1 in accordance with some embodiments of the present invention.

FIG. 6 is a waveform diagram of a first baseband current i_{rp,BPF}(t), a low frequency current i_{rp,PDC}(t), and a baseband current peak value I_{rp,PDC} in the resonant circuit 102 of FIG. 1 in accordance with some embodiments of the present invention.

FIG. 7 is a waveform diagram of the resonant tank voltage Vᵣₚ, a baseband voltage V_{rp,BPF}, and the first baseband current i_{rp, BPF} in the resonant circuit 102 of FIG. 1 in accordance with some embodiments of the present invention.

FIG. 8A is spectrum diagram of the input power Pᵣ calculated by a processor 114 based on the switching frequency fₛ in accordance with some embodiments of the present invention.

FIG. 8B is spectrum diagram of the input power Pᵣ calculated by the processor 114 based on the switching frequency fₛ and the sideband frequency fₛ±kf_{ac} in accordance with some embodiments of the present invention.

FIG. 9A is a schematic diagram of the resonant circuit 102 in FIG. 1 in accordance with some embodiments of the present invention.

FIG. 9B is a schematic diagram of the resonant circuit 102 in FIG. 1 in accordance with some embodiments of the present invention.

FIG. 10 is a flow chart of a method to estimate input power input to a resonant tank in a resonant circuit in accordance with some embodiments of the present invention.

### DETAILED DESCRIPTION OF THE INVENTION

In order to make the above purposes, features, and advantages of some embodiments of the present invention more comprehensible, the following is a detailed description in conjunction with the accompanying drawing.

Certain terms are used throughout the description and following claims to refer to particular components. As one skilled in the art will understand, electronic equipment manufacturers may refer to a component by different names. This document does not intend to distinguish between components that differ in name but not function. It is understood that the words “comprise”, “have” and “include” are used in an open-ended fashion, and thus should be interpreted to mean “include, but not limited to . . . ”. Thus, when the terms “comprise”, “have” and/or “include” used in the present invention are used to indicate the existence of specific technical features, values, method steps, operations, units and/or components. However, it does not exclude the possibility that more technical features, numerical values, method steps, work processes, units, components, or any combination of the above can be added.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for explaining and not used for limiting the present invention. Regarding the drawings, the drawings show the general characteristics of methods, structures, and/or materials used in specific embodiments. However, the drawings should not be construed as defining or limiting the scope or properties encompassed by these embodiments. For example, for clarity, the relative size, thickness, and position of each layer, each area, and/or each structure may be reduced or enlarged.

When the corresponding component such as layer or area is referred to as being “on another component”, it may be directly on this other component, or other components may exist between them. On the other hand, when the component is referred to as being “directly on another component (or the variant thereof)”, there is no component between them. Furthermore, when the corresponding component is referred to as being “on another component”, the corresponding component and the other component have a disposition relationship along a top-view/vertical direction, the corresponding component may be below or above the other component, and the disposition relationship along the top-view/vertical direction is determined by the orientation of the device.

It should be understood that when a component or layer is referred to as being “connected to” another component or layer, it can be directly connected to this other component or layer, or intervening components or layers may be present. In contrast, when a component is referred to as being “directly connected to” another component or layer, there are no intervening components or layers present.

The electrical connection or coupling described in this disclosure may refer to direct connection or indirect connection. In the case of direct connection, the endpoints of the components on the two circuits are directly connected or connected to each other by a conductor line segment, while in the case of indirect connection, there are switches, diodes, capacitors, inductors, resistors, other suitable components, or a combination of the above components between the endpoints of the components on the two circuits, but the intermediate component is not limited thereto.

The words “first”, “second”, “third”, “fourth”, “fifth”, and “sixth” are used to describe components. They are not used to indicate the priority order of or advance relationship, but only to distinguish components with the same name.

It should be noted that the technical features in different embodiments described in the following can be replaced, recombined, or mixed with one another to constitute another embodiment without departing from the spirit of the present invention.

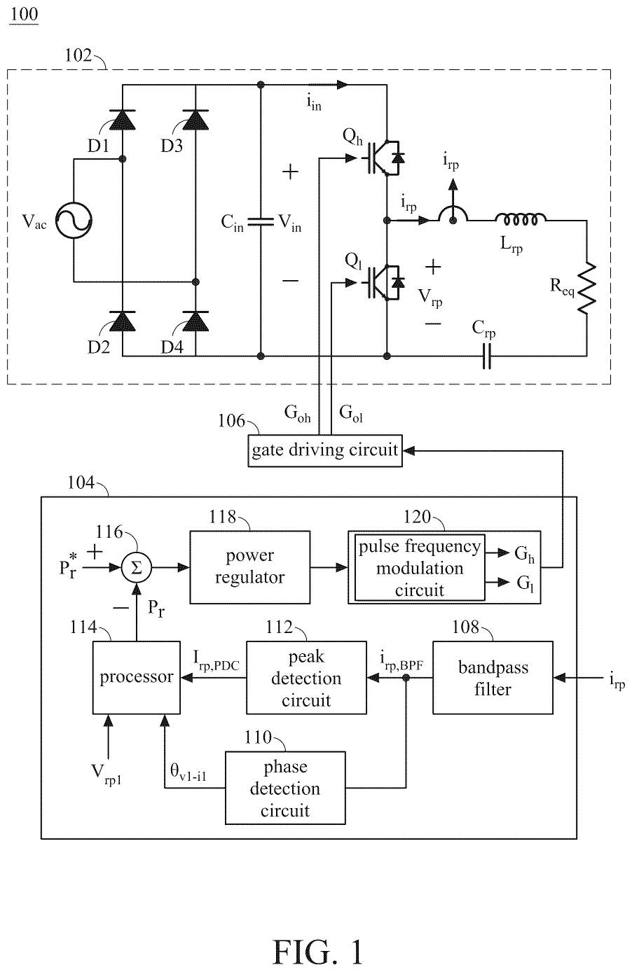

FIG. 1 is a schematic diagram of an electronic device 100 in accordance with some embodiments of the present invention. As shown in FIG. 1, the electronic device 100 includes a resonant circuit 102, a power control block circuit 104, and a gate driving circuit 106. In some embodiments, the resonant circuit 102 may be, for example, a part of circuits in an induction cooker, but the present invention is not limited thereto. The power control block circuit 104 calculates the input power Pᵣ input to a resonant tank in the resonant circuit 102. The frequency of the pulse signal Gₕ or the pulse signal Gₗ used to drive the resonant circuit 102 corresponds to the input power Pᵣ. The power control block circuit 104 drives the resonant circuit 102 through the gate driving circuit 106. In some embodiments, the power control block circuit 104 includes a bandpass filter 108, a phase detection circuit 110, a peak detection circuit 112, a processor 114, a subtractor 116, a power regulator 118, and a pulse frequency modulation circuit 120.

The bandpass filter 108 receives a resonant current iᵣₚ input to the resonant tank in the resonant circuit 102, and filters the resonant current iᵣₚ to generate a first baseband current i_{rp,BPF}. The phase detection circuit 110 is electrically connected to the bandpass filter 108, and calculates a phase difference θᵥ₁₋ᵢ₁ between the first baseband current i_{rp,BPF} and a rising edge of a resonant tank voltage Vᵣₚ. The peak detection circuit 112 is electrically connected to the bandpass filter 108, and calculates a first baseband current i_{rp,BPF} to generate a baseband current peak value I_{rp,PDC}. The processor 114 is electrically connected the phase detection circuit 110 and the peak detection circuit 112, and performs a fast Fourier transform on the resonant tank voltage Vᵣₚ to obtain a resonant tank baseband voltage Vᵣₚ₁. The processor 114 calculates the input power Pᵣ according to the resonant tank baseband voltage Vᵣₚ₁, the baseband current peak value I_{rp,PDC}, and the phase difference θᵥ₁₋ᵢ₁.

In detail, the processor 114 calculates the input power Pᵣ using the following equation 1.

$${P}_{r} = \frac{11}{9 π} {V}_{rp 1} {I}_{r p , P D C} cos ( {θ}_{v 1} - {θ}_{i 1} ) . \qquad equation 1$$

In equation 1, Pᵣ is the input power, Vᵣₚ₁ is the resonant tank baseband voltage, I_{rp,PDC} is the baseband current peak value, and θᵥ₁−θᵢ₁ is the phase difference between the first baseband current i_{rp,BPF} and the rising edge of the resonant tank voltage Vᵣₚ.

The subtractor 116 is electrically connected to the processor 114, receives reference input power

$${P}_{r}^{*}$$

and the input power Pᵣ from the processor 114, and subtracts the reference input power

$${P}_{r}^{*}$$

and the input power Pᵣ to obtain the power difference. The power regulator 118 is electrically connected to the subtractor 116, and adjusts the input power Pᵣ according to the power difference to obtain the total input power. In some embodiments, the reference input power

$${P}_{r}^{*}$$

may be, for example, the target power set by the user, but the present invention is not limited thereto. For example, when the input power Pᵣ is less than the reference input power

$${P}_{r}^{*} ,$$

the power regulator 118 may correspondingly increase the power value of the input power Pᵣ to obtain the total input power. Moreover, when the input power Pᵣ is larger than the reference input power

$${P}_{r}^{*} ,$$

the power regulator 118 may reduce the power value of the input power Pᵣ to obtain the total input power.

The pulse frequency modulation circuit 120 is electrically connected to the power regulator 118, adjusts the frequency (for example, the switching frequency) of a pulse signal according to the total input power, and outputs the pulse signal. In some embodiments of FIG. 1, the pulse signal may be, for example, the pulse signal Gₕ and the pulse signal Gₗ, but the present invention is not limited thereto. The gate driving circuit 106 is electrically connected to the pulse frequency modulation circuit 120, and outputs a driving signal Gₒₕ and a driving signal Gₒₗ according to the pulse signal Gₕ and the pulse signal Gₗ to drive the resonant circuit 102.

In some embodiments of FIG. 1, the resonant circuit 102 includes an AC power source V_{ac}, a diode D₁, a diode D₂, a diode D₃, a diode D₄, a capacitor Cᵢₙ, a transistor Qₕ, a transistor Qₗ, an inductor Lᵣₚ, a capacitor Cᵣₚ, and a load resistor R_{eq}. One end of the AC power source V_{ac} is electrically connected to the first end of the diode D₁ and the second end of the diode D₂. The other end of the power source V_{ac} is electrically connected to first end of the diode D₃ and the second end of the diode D₄. The second end of the diode D₁ is electrically connected to the second end of the diode D₃. The first end of the diode D₂ is electrically connected to the first end of the diode D₄. The diode D₁, the diode D₂, the diode D₃, and the diode D₄ use the physics feature that signals can only pass from their first end to their second end, but cannot pass from their second end to their first end, to perform a rectification operation on the signal output by the AC power source V_{ac} to obtain the input current iᵢₙ and the input voltage vᵢₙ generated across the capacitor Cᵢₙ. Both ends of the capacitor Cᵢₙ are connected across the second end of the diode D₃ and the first end of the diode D₄ respectively.

The control end of the transistor Qₕ receives the driving signal Gₒₕ from the gate driving circuit 106. The first end of the transistor Qₕ is electrically connected to the second end of the diode D₃. The second end of the transistor Qₕ is electrically connected to the first end of the transistor Qₗ. The control end of the transistor Qₗ receives the driving signal Gₒₗ from the gate driving circuit 106. The first end of the transistor Qₗ is electrically connected to the inductor Lᵣₚ. The second end of the transistor Qₗ is electrically connected to the first end of the diode D₄ and the capacitor Cᵣₚ. The resonant tank of the resonant circuit 102 includes the inductor Lᵣₚ, the capacitor Cᵣₚ, and the load resistor R_{eq}, but the present invention is not limited thereto. The voltage across the first end and the second end of the transistor Qₗ is equal to the resonant tank voltage Vᵣₚ. The current flowing from the second end of the transistor Qₕ to the inductor Lᵣₚ is equal to the resonant current iᵣₚ.

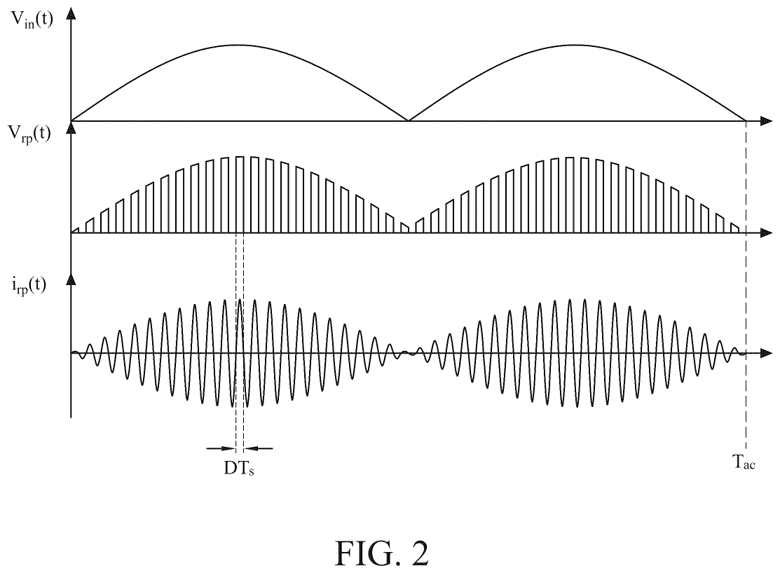

FIG. 2 is a waveform diagram of an input voltage Vᵢₙ(t), a resonant tank voltage Vᵣₚ(t), and a resonant current iᵣₚ(t) in a resonant circuit 102 of FIG. 1 in accordance with some embodiments of the present invention. As shown in FIG. 2, in an AC period T_{ac}, due to the rectification by the diode D₁, the diode D₂, the diode D₃, and the diode D₄, the input voltage Vᵢₙ(t) has a positive waveform with two peaks. In some embodiments, the AC period T_{ac} is the reciprocal of the frequency f_{ac} of the AC power source V_{ac}, which may be, for example, the reciprocal of the mains frequency 60 Hz. The transistor Qₕ and the transistor Qₗ load the frequency information of the driving signal Gₒₕ and the driving signal Gₒₗ into the waveform of the input voltage Vᵢₙ(t), thereby generating the waveform of the resonant tank voltage Vᵣₚ (t). In some embodiments, the resonant tank voltage Vᵣₚ(t) can be expressed by the following equation 2 after Fourier series expansion.

$${V}_{rp} ( t ) = {V}_{c} + {\sum }_{k = even}^{∞} {v}_{r p , k} ( t ) + {\sum }_{n = o d d}^{∞} [ {v}_{r p n} ( t ) + {v}_{r p n , s b k} ( t ) ] . \qquad equation 2$$

In equation 2,

$${V}_{c} = \frac{2 D {V}_{p}}{π} \qquad ( equation 3 )$$

is provided. Vₚ is the peak value of the sine wave voltage of the AC power source V_{ac}, and D is the ratio of the time for the upper arm switch (for example, the transistor Qₕ) closing to the switching period Tₛ.

In equation 2,

$${v}_{r p , k} ( t ) = \frac{- 4 D {V}_{p}}{π ( {k}^{2} - 1 )} cos ( 2 k π {f}_{a c} t ) \qquad ( equation 4 )$$

is provided. Vₚ is the peak value of the sine wave voltage of the AC power source V_{ac}, D is the ratio of the time for the upper arm switch (for example, the transistor Qₕ) closing to the switching period Tₛ, and f_{ac} is the frequency of the AC power source V_{ac}.

In equation 2,

$${v}_{r p n} ( t ) = \frac{2 \sqrt{2} {V}_{p}}{n {π}^{2}} \sqrt{1 - cos ( 2 n D π )} sin ( 2 n π {f}_{s} t + {θ}_{v n} ) \qquad ( equation 5 )$$

is provided. Vₚ is the peak value of the sine wave voltage of the AC power source V_{ac}, n is the n times harmonic of the switching frequency (n is an odd number), D is the ratio of the time for the upper arm switch (for example, the transistor Qₕ) closing to the switching period Tₛ, and fₛ is the switching frequency of the switches (for example, the transistor Qₕ and the transistor Qₗ). θᵥₙ is shown in the following equation 7.

In equation 2,

$${v}_{rpn , sbk} ( t ) = \frac{- 2 \sqrt{2} {v}_{p}}{n {π}^{2}} \sqrt{1 - cos ( 2 nD π )}$$

$${Σ}_{k = even}^{∞} ( \frac{sin [ ( {nf}_{s} \pm {kf}_{ac} ) 2 πt + {θ}_{vn} ]}{{k}^{2} - 1} )$$

is provided. Vₚ is the peak value of the sine wave voltage of the AC power source V_{ac}, n is the n times harmonic of the switching frequency (n is an odd number), D is the ratio of the time for the upper arm switch (for example, the transistor Qₕ) closing to the switching period Tₛ, fₛ is the switching frequency of the switches (for example, the transistor Qₕ and the transistor Qₗ), and f_{ac} is the frequency of the AC power source V_{ac}. θᵥₙ is shown in the following equation 7.

In equations 5 and 6,

$${θ}_{v n} = {tan}^{- 1} ( \frac{sin ( 2 nD π )}{1 - cos ( 2 nD π )} ) \qquad ( equation 7 )$$

is provided. n is the n times harmonic of the switching frequency (n is an odd number), and D is the ratio of the time for the upper arm switch (for example, the transistor Qₕ) closing to the switching period Tₛ.

As shown in the above equations 2 to 7, the resonant tank voltage Vᵣₚ includes the signal component of the frequency f_{ac} in the AC power source V_{ac} and the signal component with its harmonic frequency (k·f_{ac}), plus the signal component of the high-frequency switching frequency fₛ and the signal component with its harmonic frequency (n·fₛ) and its sideband frequency (n fₛ±kf_{ac}).

Similarly, in some embodiments of FIG. 2, the resonant current iᵣₚ(t) also carries the information of the period DTₛ, which is the same as the resonant tank voltage Vᵣₚ(t) carrying the information of the period DTₛ. D is the ratio of the time for the upper arm switch (for example, the transistor Qₕ) closing to the switching period Tₛ.

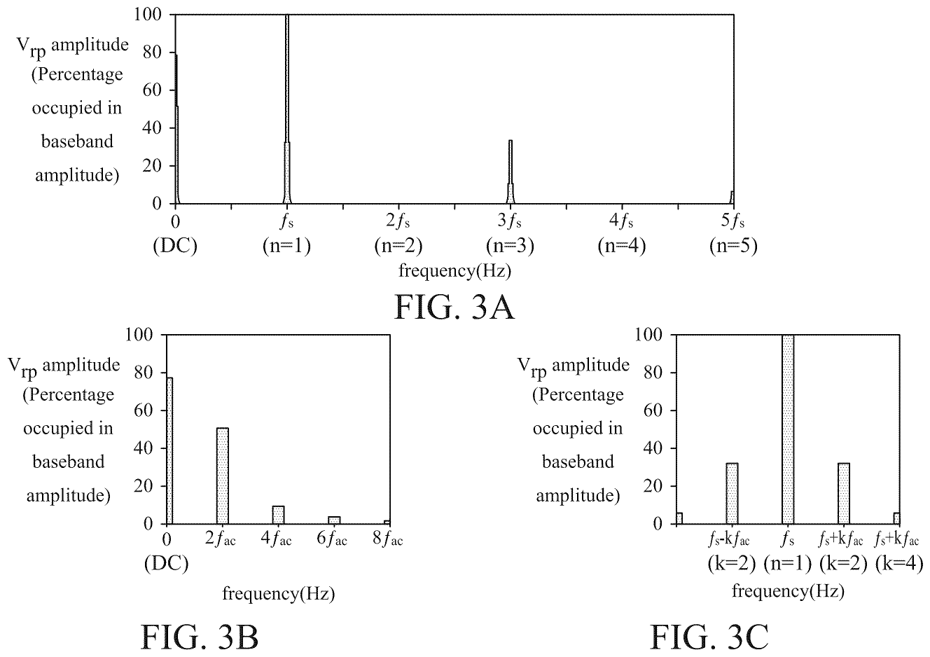

FIG. 3A is a spectrum diagram of the resonant tank voltage Vᵣₚ in the resonant circuit 102 of FIG. 1 based on a switching frequency fₛ in accordance with some embodiments of the present invention. As shown in FIG. 3A, the resonant tank voltage Vᵣₚ has the maximal amplitude at the switching frequency fₛ (that is, its resonant frequency, n=1). The resonant tank voltage Vᵣₚ has the sub-maximal amplitude at frequency 0 (for example, the DC). The resonant tank voltage Vᵣₚ has the sub-minimal amplitude at 3 times the switching frequency 3 fₛ (n=3). The resonant tank voltage Vᵣₚ has the minimal amplitude at 5 times the switching frequency 5fₛ (n=5).

FIG. 3B is a spectrum diagram of the resonant tank voltage Vᵣₚ in the resonant circuit 102 of FIG. 1 based on a mains frequency f_{ac} in accordance with some embodiments of the present invention. As shown in FIG. 3B, the resonant tank voltage Vᵣₚ has the maximal amplitude at frequency 0 (for example, the DC). The resonant tank voltage Vᵣₚ has the sub-maximal amplitude at 2 times the mains frequency 2f_{ac} of the AC power source V_{ac}. The resonant tank voltage Vᵣₚ has the third-maximal amplitude at 4 times the mains frequency 4 f_{ac}. The resonant tank voltage Vᵣₚ has the sub-minimal amplitude at 6 times the mains frequency 6f_{ac}. The resonant tank voltage Vᵣₚ has the minimal amplitude at 8 times the mains frequency 8f_{ac}.

FIG. 3C is a spectrum diagram of the resonant tank voltage Vᵣₚ in the resonant circuit 102 of FIG. 1 based on the switching frequency fₛ and the sideband frequency fₛ±kf_{ac} in accordance with some embodiments of the present invention. As shown in FIG. 3C, the resonant tank voltage Vᵣₚ has the maximal amplitude at the switching frequency fₛ (n=1). The resonant tank voltage Vᵣₚ has the same amplitude at the frequency (n·fₛ+k·f_{ac}) and the frequency (n·fₛ−k·f_{ac}).

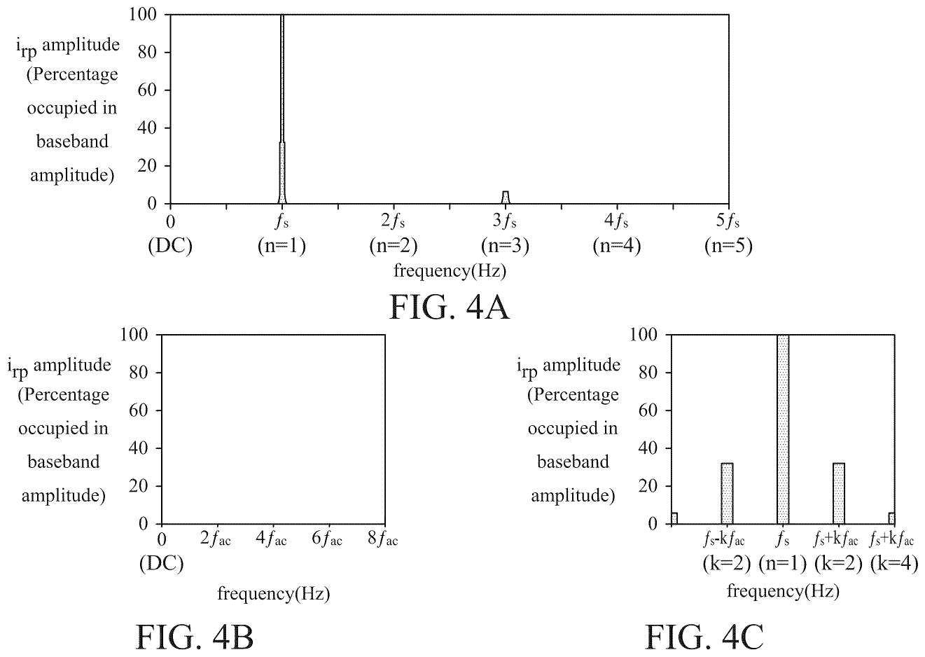

FIG. 4A a spectrum diagram of the resonant current iᵣₚ in the resonant circuit 102 of FIG. 1 based on the switching frequency fₛ in accordance with some embodiments of the present invention. As shown in FIG. 4A, since the capacitor Cᵣₚ will block the DC component in the resonant current iᵣₚ, the amplitude of the resonant current iᵣₚ at frequency 0 (that is, the DC) is 0. The resonant current iᵣₚ has the maximal amplitude at the switching frequency fₛ (n=1). The resonant current iᵣₚ has the minimal amplitude at 3 times the switching frequency 3fₛ (n=3).

FIG. 4B a spectrum diagram of the resonant current iᵣₚ in the resonant circuit 102 of FIG. 1 based on the mains frequency f_{ac} in accordance with some embodiments of the present invention. As shown in FIG. 4B, since the capacitor Cᵣₚ will block the DC component and the low frequency component in the resonant current iᵣₚ, the amplitude of the resonant current iᵣₚ at frequency 0 (that is, the DC), 2 times the mains frequency 2f_{ac} of the AC power source V_{ac}, 4 times the mains frequency 4f_{ac} of the AC power source V_{ac}, 6 times the mains frequency 6f_{ac} of the AC power source V_{ac}, and 8 times the mains frequency 8f_{ac} of the AC power source V_{ac} is all 0.

FIG. 4C a spectrum diagram of the resonant current iᵣₚ in the resonant circuit 102 of FIG. 1 based on the switching frequency fₛ and the sideband frequency fₛ±kf_{ac} in accordance with some embodiments of the present invention. As shown in FIG. 4C, the resonant current iᵣₚ has the maximal amplitude at the switching frequency fₛ (n=1). The resonant current iᵣₚ has the same amplitude at the frequency (n·fₛ+k·f_{ac}) and the frequency (n·fₛ−k·f_{ac}).

Please refer to FIG. 3A, FIG. 3B, FIG. 4A, and FIG. 4B at the same time. Power is equal to voltage multiplied by current. Since the capacitor Cᵣₚ will block the DC component and the low frequency component in the resonant current iᵣₚ, the voltage V_{c} in equation 3 and the voltage V_{rp,k}(t) in equation 4 do not perform work. Please refer to FIG. 3C and FIG. 4C at the same time. The main work components of the resonant tank voltage Vᵣₚ include the resonant tank baseband voltage Vᵣₚ₁ that does work at the switching frequency fₛ and the low-order sideband frequency resonant voltage that does work at the frequency fₛ±kf_{ac}), that is, the voltage V_{rp1,sbk}.

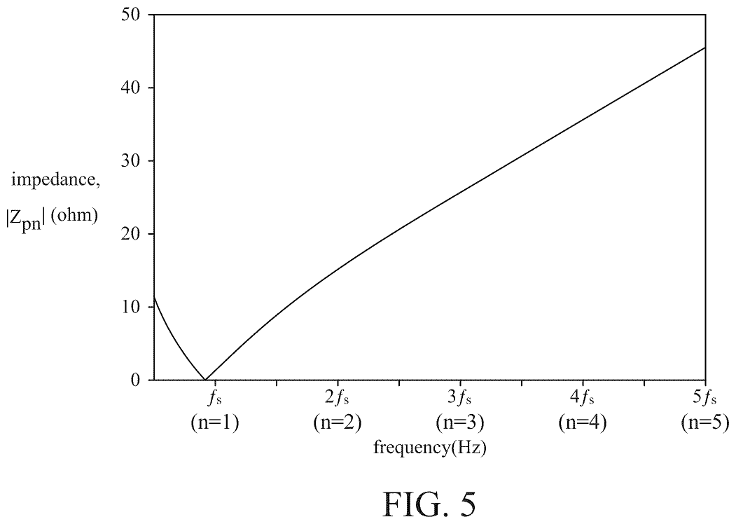

FIG. 5 is a diagram of a relationship between a resonant tank impedance |Zₚₙ| and both the switching frequency fₛ and its harmonic frequency in the resonant circuit 102 of FIG. 1 in accordance with some embodiments of the present invention. As shown in FIG. 5, the resonant tank impedance |Zₚₙ| has a minimum value near the switching frequency fₛ, which is the resonant frequency or near the resonant frequency. Since the impedance value of the resonant tank impedance |Zₚₙ| at 3 times the switching frequency 3fₛ and at 5 times the switching frequency 5fₛ is much larger than the baseband impedance Zₚ₁, and the impedance value of the resonant tank impedance |Zₚₙ| at the low-order sideband frequency (fₛ±k·f_{ac}) will be close to the baseband impedance Zₚ₁, the main work components of the resonant tank voltage Vᵣₚ include the resonant tank baseband voltage Vᵣₚ₁ that does work at the switching frequency fₛ and the low-order sideband resonant voltage V_{rp1,sbk} that does work at the frequency (fₛ±k·f_{ac}).

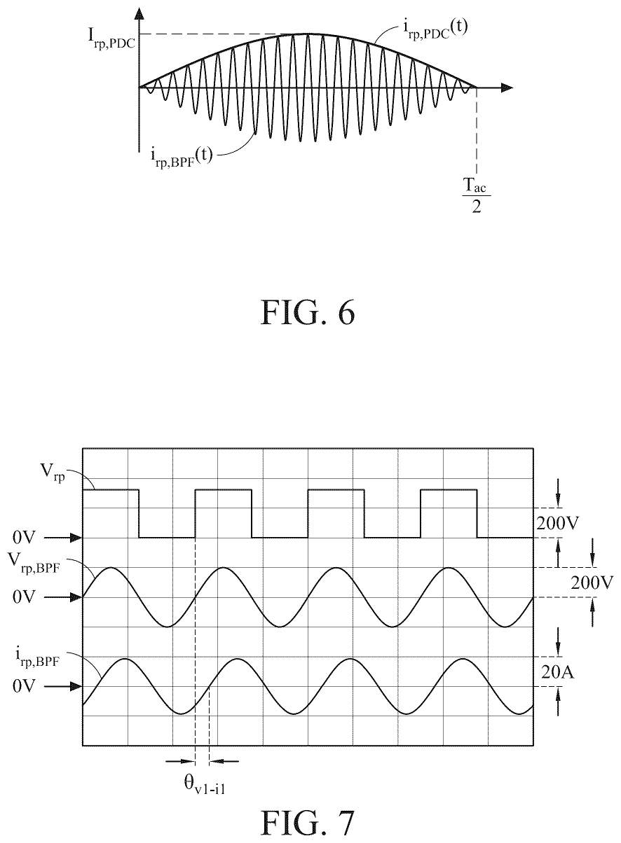

FIG. 6 is a waveform diagram of a first baseband current i_{rp,BPF} (t), a low frequency current i_{rp,PDC} (t), and a baseband current peak value I_{rp,PDC} in the resonant circuit 102 of FIG. 1 in accordance with some embodiments of the present invention. FIG. 6 first discloses the waveform diagram of the first baseband current i_{rp, BPF} (t) generated after filtering by the bandpass filter 108 in the period

$$\frac{{T}_{a c}}{2} .$$

The AC period T_{ac} is the reciprocal of the frequency f_{ac} of the AC power source V_{ac}, which can be, for example, the reciprocal of the mains frequency 60 Hz. Next, the peak detection circuit 112 performs peak detection on the first baseband current i_{rp, BPF} (t) to generate the low frequency current i_{rp,PDC} (t) in FIG. 6. The baseband current peak value I_{rp,PDC} is the maximal amplitude of the low frequency current i_{rp,PDC} (t).

In detail, the first baseband current i_{rp,BPF} (t) can be expressed by the following equation 8.

$${i}_{rp , BPF} ( t ) = {i}_{rp 1} ( t ) + {\sum }_{k = even}^{∞} {i}_{r p 1 , s b k} ( t ) . \qquad equation 8$$

In equation 8, iᵣₚ₁(t)=Iᵣₚ₁ sin(2×fₛ+θᵢ₁) (equation 9) is provided. Iᵣₚ₁ is the baseband current peak value, and θᵢ₁ is the phase of the baseband current.

In equation 8, i_{rp1,sbk}(t)=I_{rp1,sbk} sin[(fₛ±kf_{ac}) 2πt+θᵢ₁] (equation 10) is provided. I_{rp1,sbk} is the current peak value of k times the sideband near the baseband (i.e., the switching frequency fₛ).

In detail, the low frequency current i_{rp,PDC} (t) can be expressed by the following equation 11.

$${i}_{rp , PDC} ( t ) = {I}_{rp 1} + {\sum }_{k = e v e n}^{∞} \frac{- 2}{{k}^{2} - 1} cos ( 2 k π {f}_{a c} t ) . \qquad equation 11$$

Using the Taylor series expansion of the arctangent function, equation 11 can be written as the following equation 12.

$${i}_{rp , PDC} ( t ) = {I}_{r p 1} + ( \frac{π}{2} - 1 ) {I}_{rp 1} cos ( 2 k π {f}_{a c} t ) . \qquad equation 12$$

When cos(2kπf_{ac}t)=1 is provided, the peak value of i_{rp,PDC}(t) can be obtained. That is, the baseband current peak value I_{rp,PDC} can be expressed by the following equation 13.

$${I}_{r p , P D C} = \frac{3 π}{2} {I}_{rp 1 , s b 2} . \qquad equation 13$$

I_{rp1,sb2} is the peak value of the first sideband frequency (fₛ±2f_{ac}) on both sides of the baseband component.

FIG. 7 is a waveform diagram of the resonant tank voltage Vᵣₚ, a baseband voltage V_{rp,BPF}, and the first baseband current i_{rp,BPF} in the resonant circuit 102 of FIG. 1 in accordance with some embodiments of the present invention. As shown in FIG. 7, the resonant tank voltage Vᵣₚ is a square wave signal with an amplitude higher than 200V and a switching period Tₛ. The duty cycle of the resonant tank voltage Vᵣₚ is 50%. The switching period Tₛ is the reciprocal of the switching frequency fₛ. In some embodiments, if the bandpass filter 108 filters the resonant tank voltage Vᵣₚ, a baseband voltage V_{rp,BPF} with an amplitude equal to 200V and a switching period Tₛ can be obtained. The baseband voltage V_{rp,BPF} is a sine wave signal. FIG. 7 discloses the waveform diagram of the first baseband current i_{rp,BPF} generated after being filtered by the bandpass filter 108. As shown in FIG. 7, the time point when the waveform of the baseband voltage V_{rp,BPF} passes through the voltage 0 point is the same as the time point when the rising edge of the resonant tank voltage Vᵣₚ occurs. Therefore, the present invention does not need to obtain the baseband voltage V_{rp,BPF} in advance. Instead, the phase detection circuit 110 directly calculates the phase difference θᵥ₁₋ᵢ₁.

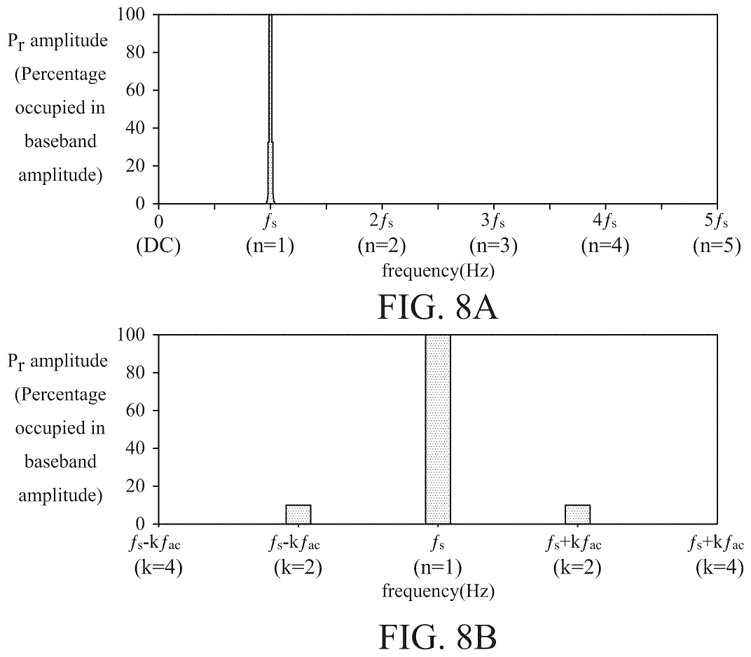

FIG. 8A is spectrum diagram of the input power Pᵣ calculated by a processor 114 based on the switching frequency fₛ in accordance with some embodiments of the present invention. As shown in FIG. 8A, the input power Pᵣ has the maximum amplitude at and near the switching frequency fₛ (n=1).

FIG. 8B is spectrum diagram of the input power Pᵣ calculated by the processor 114 based on the switching frequency fₛ and the sideband frequency fₛ±kf_{ac} in accordance with some embodiments of the present invention. As shown in FIG. 8B, the input power Pᵣ has the maximal amplitude at the switching frequency fₛ (n=1), which is the baseband power. The input power Pᵣ has a sub-maximal amplitude value at the low-order sideband frequency (fₛ±k f_{ac}), which is the maximal sideband power.

In detail, the input power Pᵣ can be expressed by the following equation 14.

$${P}_{r} = {P}_{r 1} + 2 {P}_{r 1 , s b 2} = \frac{11}{18} {V}_{rp 1} {I}_{rp 1} cos ( {θ}_{v 1} - {θ}_{i 1} ) . \qquad equation 14$$

In equation 14,

$${P}_{r 1} = \frac{1}{2} {V}_{rp 1} {I}_{rp 1} cos ( {θ}_{v 1} - {θ}_{i 1} ) \qquad ( equation 15 )$$

is provided.

In equation 14,

$${P}_{r 1 , s b 2} = \frac{1}{9} {P}_{r 1} \qquad ( equation 16 )$$

is provided.

The present invention substitutes equation 13 into equation 14 to obtain equation 1.

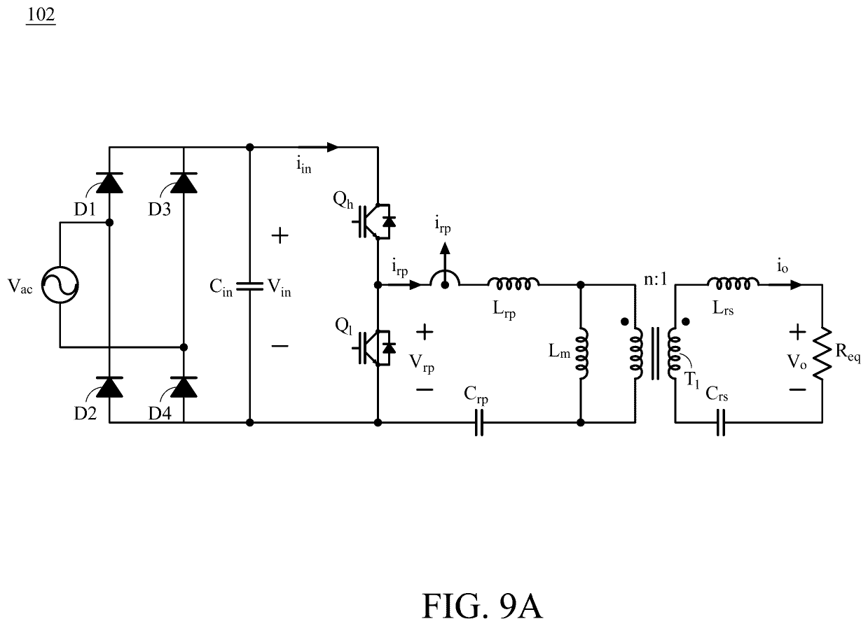

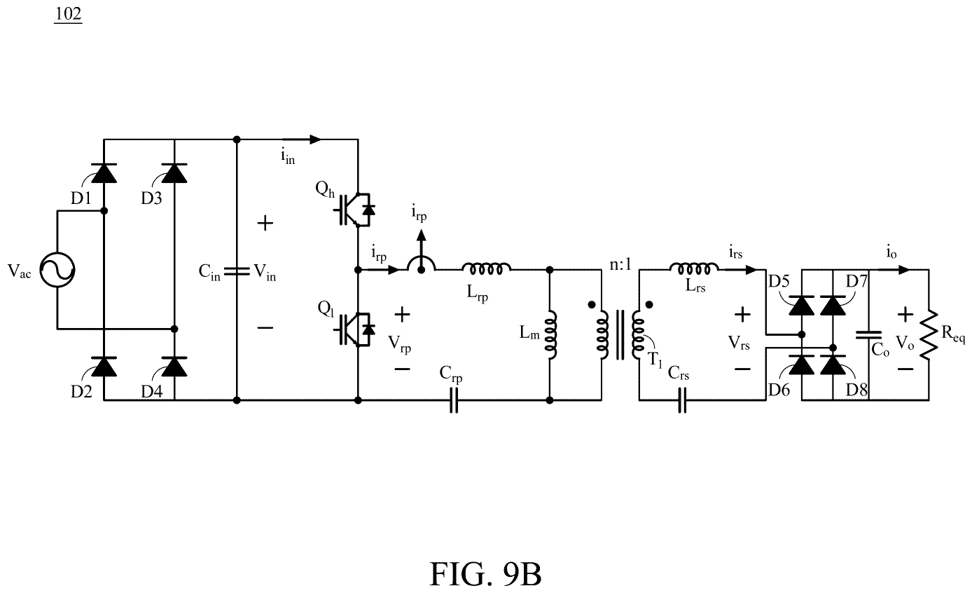

FIG. 9A is a schematic diagram of the resonant circuit 102 in FIG. 1 in accordance with some embodiments of the present invention. In some embodiments of FIG. 9A, the resonant circuit 102 is a wireless power transmission circuit of a pair of series resonant circuits. In some embodiments of FIG. 9A, the resonant circuit 102 includes the AC power source V_{ac}, the diode D₁, the diode D₂, the diode D₃, the diode D₄, the capacitor Cᵢₙ, the transistor Qₕ, the transistor Qₗ, the inductor Lᵣₚ, the capacitor Cᵣₚ, and the inductor Lₘ. One end of the AC power source V_{ac} is electrically connected to the first end of the diode D₁ and the second end of the diode D₂. The other end of the AC power source V_{ac} is electrically connected to the first end of the diode D₃ and the second end of the diode D₄. The second end of the diode D₁ is electrically connected to the second end of the diode D₃. The first end of the diode D₂ is electrically connected to the first end of the diode D₄. The diode D₁, the diode D₂, the diode D₃, and the diode D₄ use the physics feature that signals can only pass from their first end to their second end, but cannot pass from their second end to their first end, to perform a rectification operation on the signal output by the AC power source V_{ac} to obtain the input current iᵢₙ and the input voltage vᵢₙ generated across the capacitor Cᵢₙ. Both ends of the capacitor Cᵢₙ are connected across the second end of the diode D₃ and the first end of the diode D₄ respectively.

The control end of the transistor Qₕ receives the driving signal Gₒₕ from the gate driving circuit 106. The first end of the transistor Qₕ is electrically connected to the second end of the diode D₃. The second end of the transistor Qₕ is electrically connected to the first end of the transistor Qₗ. The control end of the transistor Qₗ receives the driving signal Gₒₗ from the gate driving circuit 106. The first end of the transistor Qₗ is electrically connected to the inductor Lᵣₚ. The second end of the transistor Qₗ is electrically connected to the first end of the diode D₄ and the capacitor Cᵣₚ. The resonant tank of the resonant circuit 102 includes the inductor Lᵣₚ, the capacitor Cᵣₚ, and the load resistor R_{eq}, but the present invention is not limited thereto. The voltage across the first end and the second end of the transistor Qₗ is equal to the resonant tank voltage Vᵣₚ. The current flowing from the second end of the transistor Qₕ to the inductor Lᵣₚ is equal to the resonant current iᵣₚ.

In some embodiments of FIG. 9A, the resonant circuit 102 further includes a transformer T₁, an inductor Lᵣₛ, a capacitor Cᵣₛ, and a load resistor R_{eq}. The turns ratio between the primary side and the secondary side of the transformer T₁ is n: 1. The primary side of the transformer T₁ is electrically connected between the inductor Lᵣₚ and the capacitor Cᵣₚ. The secondary side of transformer T₁ is electrically connected between the inductor Lᵣₛ and capacitor Cᵣₛ. The secondary side of the transformer T₁ induces an output current iₒ based on the resonant current iᵣₚ of its primary side. When the output current iₒ flows through the load resistor R_{eq}, the output voltage Vₒ is generated. The output voltage Vₒ is an AC signal.

In some embodiments of FIG. 9A, the output power Pₒ can be expressed by the following equation 17.

$${P}_{o} = \frac{1}{T} {\int }_{T} {v}_{o} {i}_{o} d t = {P}_{r} - {P}_{c o i l} . \qquad equation 17$$

In equation 17, Pᵣ can be expressed by equation 1. P_{coil} is the loss between wireless power transmission coils.

FIG. 9B is a schematic diagram of the resonant circuit 102 in FIG. 1 in accordance with some embodiments of the present invention. The main difference between FIG. 9B and FIG. 9A is that, in FIG. 9B, in addition to the transformer T₁, the inductor Lᵣₛ, the capacitor Cᵣₛ, and the load resistor R_{eq}, the resonant circuit 102 also includes a diode D₅, a diode D₆, a diode D₇, and a diode D₈. The diode D₅, the diode D₆, the diode D₇, and the diode D₈ form a full-wave rectifier circuit to convert the AC voltage Vᵣₛ between the secondary side inductance Lᵣₛ and capacitor Cᵣₛ of the transformer T₁ into DC output voltage Vₒ.

In some embodiments of FIG. 9B, the output power Pₒ can be expressed by the following equation 18.

$${P}_{o} = \frac{1}{T} {\int }_{T} {v}_{o} {i}_{o} d t = {P}_{r} - {P}_{c o i l} - {P}_{d i o d e} . \qquad equation 18$$

In equation 18, Pᵣ can be expressed by equation 1. P_{coil} is the loss between wireless power transmission coils. P_{diode} is the loss caused by diode full-wave rectification.

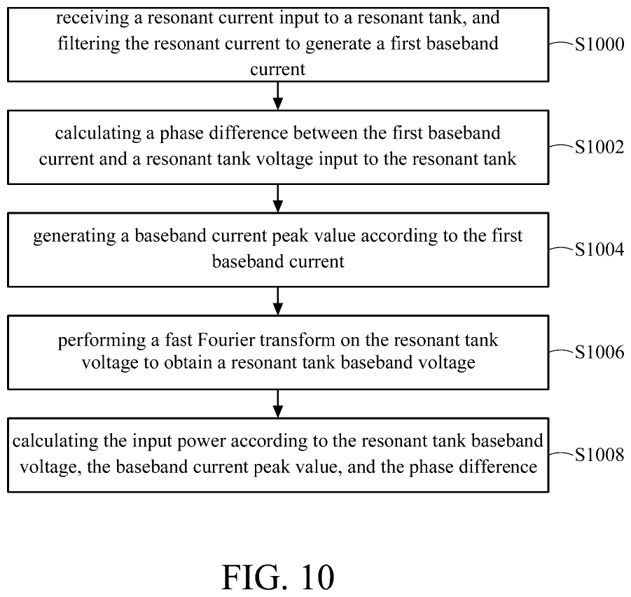

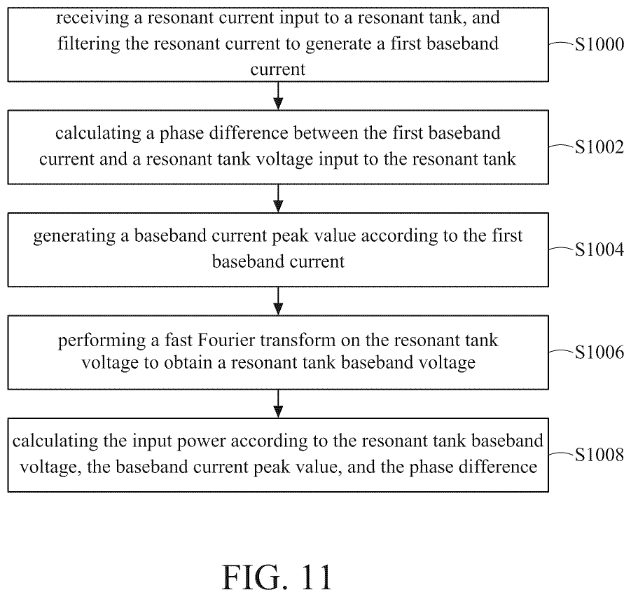

FIG. 10 is a flow chart of a method to estimate input power input to a resonant tank in a resonant circuit in accordance with some embodiments of the present invention. As shown in FIG. 10, the method to estimate input power input to a resonant tank in a resonant circuit includes the following steps. A resonant current input to the resonant tank is received, and the resonant current is filtered to generate a first baseband current (step S1000). A phase difference between the first baseband current and a resonant tank voltage input to the resonant tank is calculated (step S1002). A baseband current peak value is generated according to the first baseband current (step S1004). A fast Fourier transform is performed on the resonant tank voltage to obtain a resonant tank baseband voltage (step S1006). The input power is calculated according to the resonant tank baseband voltage, the baseband current peak value, and the phase difference (step S1008).

In some embodiments, step S1000 may be performed, for example, by the bandpass filter 108 in FIG. 1. Step S1002 may be performed, for example, by the phase detection circuit 110 in FIG. 1. Step S1004 may be performed, for example, by the peak detection circuit 112 in FIG. 1. Steps S1006 and S1008 may be performed, for example, by the processor 114 in FIG. 1.

In some embodiments, step S1008 includes calculating the input power according to the following equation. The equation is

$${P}_{r} = \frac{11}{9 π} {V}_{rp 1} {I}_{rp , PDC} cos ( {θ}_{v 1} - {θ}_{i 1} ) .$$

Pᵣ is the input power, Vᵣₚ₁ is the resonant tank baseband voltage, I_{rp,PDC} is the baseband current peak value, and θᵥ₁−θᵢ₁ is the phase difference between the first baseband current i_{rp,BPF} and the rising edge of the resonant tank voltage Vᵣₚ.

In some embodiments, the method to estimate input power input to the resonant tank in the resonant circuit further includes the following steps.

Reference input power is received, and the reference input power and the input power are subtracted to obtain the power difference. The input power is adjusted according to the power difference to obtain the total input power. The frequency of a pulse signal is adjusted according to the total input power, and the pulse signal is output. The resonant circuit is driven according to the pulse signal.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device to calculate input power input to a resonant tank in a resonant circuit, comprising:
a bandpass filter, configured to receive a resonant current input to the resonant tank, and filter the resonant current to generate a first baseband current;
a phase detection circuit, electrically connected to the bandpass filter, configured to calculate a phase difference between the first baseband current and a resonant tank voltage input to the resonant tank;
a peak detection circuit, electrically connected to the bandpass filter, configured to generate a baseband current peak value according to the first baseband current; and
a processor, electrically connected the phase detection circuit and the peak detection circuit, configured to perform a fast Fourier transform on the resonant tank voltage to obtain a resonant tank baseband voltage,
wherein the processor is configured to calculate the input power according to the resonant tank baseband voltage, the baseband current peak value, and the phase difference.

2. The electronic device as claimed in claim 1, wherein the processor calculates the input power using the following equation:
$${P}_{r} = \frac{11}{9 π} {V}_{rp 1} {I}_{rp , PDC} cos ( {θ}_{v 1} - {θ}_{i 1} ) ;$$
wherein Pᵣ is the input power, Vᵣₚ₁ is the resonant tank baseband voltage, I_{rp,PDC} is the baseband current peak value, and θᵥ₁−θᵢ₁ is the phase difference between the first baseband current and a rising edge of the resonant tank voltage.

3. The electronic device as claimed in claim 1, further comprising:
a subtractor, electrically connected to the processor, configured to receive reference input power and the input power from the processor, and subtract the reference input power and the input power to obtain a power difference.

4. The electronic device as claimed in claim 3, further comprising:
a power regulator, electrically connected to the subtractor, configured to adjust the input power according to the power difference to obtain a total input power.

5. The electronic device as claimed in claim 4, further comprising:
a pulse frequency modulation circuit, electrically connected to the power regulator, configured to adjust a frequency of a pulse signal according to the total input power, and output the pulse signal.

6. The electronic device as claimed in claim 5, further comprising:
a gate driving circuit, electrically connected to the pulse frequency modulation circuit, configured to drive the resonant circuit according to the pulse signal.

7. The electronic device as claimed in claim 1, wherein the input power comprises baseband power and maximum sideband power.

8. The electronic device as claimed in claim 1, wherein the resonant circuit is an inductor-inductor-capacitor (LLC) circuit, or a resonant circuit for wireless energy transmission, or a resonant circuit of an induction cooker.

9. A method to estimate input power input to a resonant tank in a resonant circuit, comprising:
receiving a resonant current input to the resonant tank, and filtering the resonant current to generate a first baseband current;
calculating a phase difference between the first baseband current and a resonant tank voltage input to the resonant tank;
generating a baseband current peak value according to the first baseband current;
performing a fast Fourier transform on the resonant tank voltage to obtain a resonant tank baseband voltage; and
calculating the input power according to the resonant tank baseband voltage, the baseband current peak value, and the phase difference.

10. The method as claimed in claim 9, wherein the step of calculating the input power according to the resonant tank baseband voltage, the baseband current peak value, and the phase difference comprises:
calculating the input power using an equation; wherein the equation is:
$${P}_{r} = \frac{11}{9 π} {V}_{rp 1} {I}_{rp , PDC} cos ( {θ}_{v 1} - {θ}_{i 1} ) ;$$
wherein Pᵣ is the input power, Vᵣₚ₁ is the resonant tank baseband voltage, I_{rp,PDC} is the baseband current peak value, and θᵥ₁−θᵢ₁ is the phase difference between the first baseband current and the rising edge of the resonant tank voltage.

11. The method as claimed in claim 9, further comprising:
receiving reference input power, and subtracting the reference input power and the input power to obtain the power difference;
adjusting the input power according to the power difference to obtain the total input power;
adjusting the frequency of a pulse signal according to the total input power, and outputting the pulse signal; and
driving the resonant circuit according to the pulse signal.
